(19) United States
(12) Patent Application Publication
(10) Pub. No.: US 2020/0041213 A1
(43) Pub. Date: Feb. 6, 2020

(54) FLAT-PLATE HEAT PIPE STRUCTURE

(71) Applicant: ASIA VITAL COMPONENTS CO., LTD., New Taipei City (TW)

(72) Inventor: Kuo-Chun Hsieh, New Taipei City (TW)

(21) Appl. No.: 16/600,589

(22) Filed: Oct. 14, 2019

Related U.S. Application Data
(62) Division of application No. 14/612,200, filed on Feb. 2, 2015.

(51) Int. Cl. F28D 15/02; F28D 15/04; H01L 23/427

(52) U.S. Cl. CPC F28D 15/0233; H01L 23/427; F28D 15/04

(57) ABSTRACT

A flat-plate heat pipe structure includes a main body. The main body has a first board body, a second board body, a first capillary structure and a working fluid. The first and second board bodies are overlapped and mated with each other. The first capillary structure is disposed between the first and second board bodies. The first capillary structure and the first and second board bodies together define at least one vapor passage. Accordingly, when the flat-plate heat pipe is thinned, the flat-plate heat pipe still keeps having a vapor passage, whereby the vapor-liquid circulation efficiency of the flat-plate heat pipe will not be deteriorated due to thinning.

The present application is a division of U.S. patent application Ser. No. 14/612,200, filed on Feb. 2, 2015.

### BACKGROUND OF THE INVENTION

### 1. Field of the Invention

The present invention relates generally to a flat-plate heat pipe structure, and more particularly to a flat-plate heat pipe structure with an extremely thin thickness.

### 2. Description of the Related Art

Currently, there is a trend to develop lightweight and thin electronic mobile devices. The lightweight and thin electronic mobile devices have higher and higher operation performance. However, along with the promotion of the operation performance and the reduction of the total thickness of the electronic mobile device, the internal space of the electronic mobile device for receiving electronic components is minified and limited. Moreover, when the operation performance is enhanced, the heat generated by the electronic components is increased. Therefore, a heat dissipation component is needed to help in dissipating the heat generated by the electronic components. However, due to the thinning of the electronic mobile device, the internal space of the electronic mobile device is so narrow that it is hard to arrange a heat dissipation component such as a cooling fan in the electronic mobile device. Under such circumstance, only a copper thin sheet or an aluminum thin sheet can be disposed to enlarge the heat dissipation area. However, this can hardly sufficiently enhance the heat dissipation efficiency.

In the conventional technique, a heat pipe or vapor chamber can be thinned and applied to the electronic mobile device. However, it is hard to fill powder into the thin heat pipe and sinter the powder. As a result, an extremely thin electronic mobile device can be hardly achieved. Also, after the powder is filled and sintered and when the heat pipe is flattened into a flat structure, the sintered powder or other capillary structure (mesh body or fiber body) in the heat pipe will be compressed and damaged to lose its function.

In addition, in order to more thin the conventional vapor chamber, the internal support structure is often omitted. In this case, after the vapor chamber is vacuumed and sealed, the internal chamber of the vapor chamber is likely to deform. As a result, the internal vapor passage of the conventional thin heat pipe or vapor chamber will be contracted and minified or even disappear. This will affect the vapor-liquid circulation efficiency of the heat pipe or vapor chamber. Therefore, it has become a critical issue how to improve the internal vapor-liquid circulation structure of the thin heat pipe and vapor chamber.

### SUMMARY OF THE INVENTION

It is therefore a primary object of the present invention to provide a flat-plate heat pipe structure having an ultrathin thickness. After the flat-plate heat pipe is thinned, the flat-plate heat pipe still keeps having a vapor passage.

To achieve the above and other objects, the flat-plate heat pipe structure of the present invention includes a main body. The main body has a first board body, a second board body, a first capillary structure and a working fluid. The first and second board bodies are overlapped and mated with each other. The first capillary structure is disposed between the first and second board bodies. The first capillary structure and the first and second board bodies together define at least one vapor passage.

Accordingly, after the flat-plate heat pipe is thinned, the flat-plate heat pipe still keeps having a free vapor passage. Therefore, the vapor-liquid circulation of the working fluid in the thinned flat-plate heat pipe can be still successfully performed.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a perspective exploded view of a first embodiment of the flat-plate heat pipe structure of the present invention;

FIG. 2 is a sectional assembled view of the first embodiment of the flat-plate heat pipe structure of the present invention;

FIG. 3 is a sectional assembled view of a second embodiment of the flat-plate heat pipe structure of the present invention;

FIG. 4 is a sectional assembled view of a third embodiment of the flat-plate heat pipe structure of the present invention; and

FIG. 5 is a sectional assembled view of a fourth embodiment of the flat-plate heat pipe structure of the present invention.

### DETAILED DESCRIPTION OF THE PREFERRED EMBODIMENTS

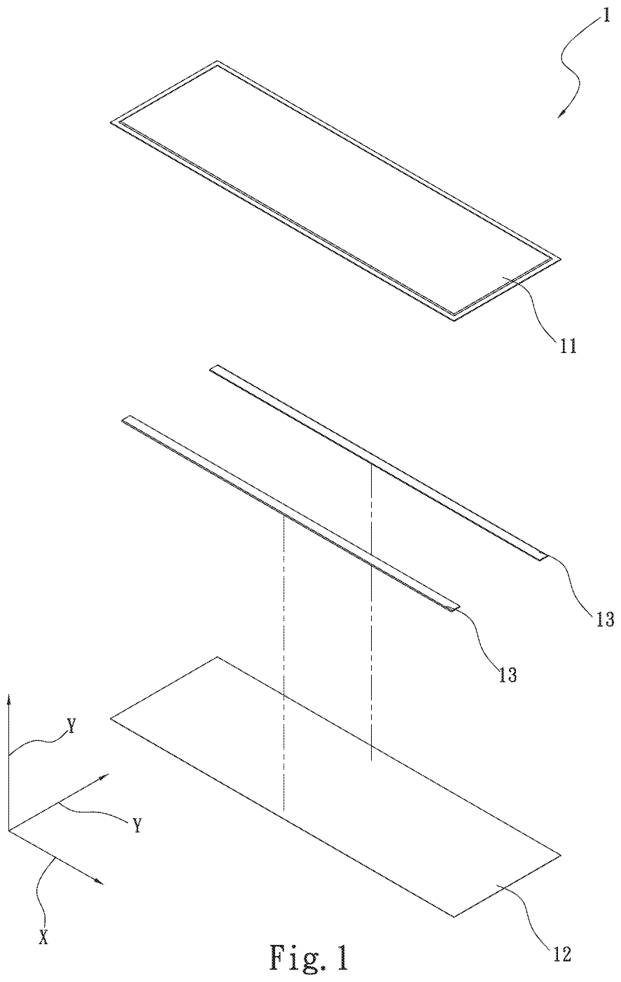

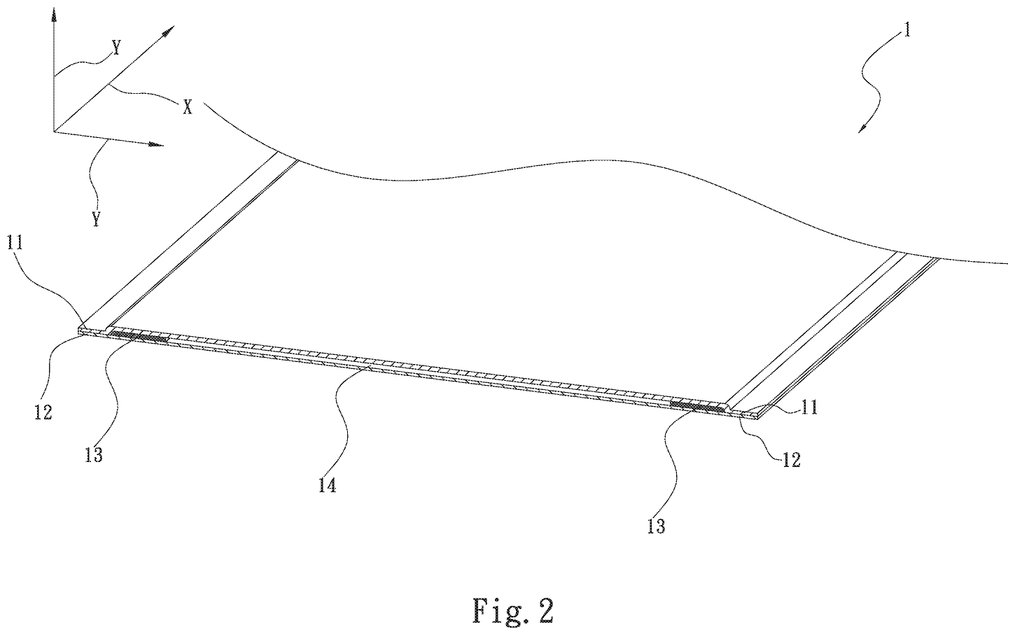

Please refer to FIGS. 1 and 2. FIG. 1 is a perspective exploded view of a first embodiment of the flat-plate heat pipe structure of the present invention. FIG. 2 is a sectional assembled view of the first embodiment of the flat-plate heat pipe structure of the present invention. According to the first embodiment, the flat-plate heat pipe structure of the present invention includes a main body 1.

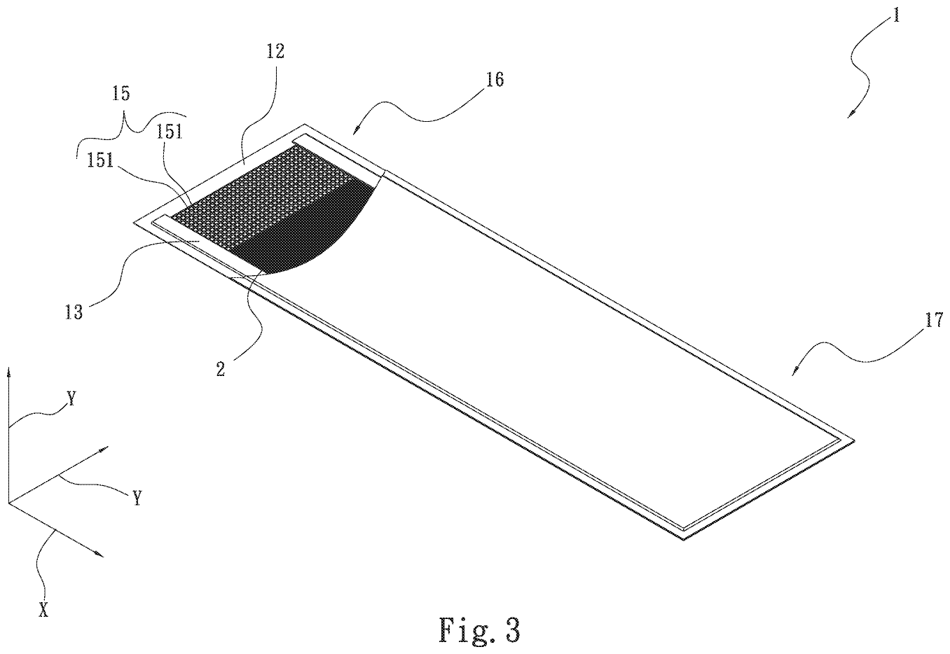

The main body 1 has a first board body 11, a second board body 12, a first capillary structure 13 and a working fluid 2 (as shown in FIG. 3). The first and second board bodies 11, 12 are overlapped and mated with each other. The first capillary structure 13 is disposed between the first and second board bodies 11, 12. The first capillary structure 13 and the first and second board bodies 11, 12 together define at least one vapor passage 14.

The first capillary structure 13 is selected from a group consisting of mesh body, fiber body, linear braided body and sintered powder body. In this embodiment, the first capillary structure 13 is, but not limited to, sintered powder body for illustration purposes only. The thickness of the first and second board bodies ranges from 0.01 mm to 0.15 mm.

In this embodiment, there is a pair of first capillary structures 13 and the vapor passage 14 is formed between the two first capillary structures 13.

Please now refer to FIG. 3, which is a sectional assembled view of a second embodiment of the flat-plate heat pipe structure of the present invention. The second embodiment is partially identical to the first embodiment in structure and technical characteristic and thus will not be repeatedly described. The second embodiment is different from the first embodiment in that the main body 1 further has a second capillary structure 15, a heat absorption section 16 and a heat dissipation section 17. The second capillary structure 15 is multiple channels 151 or braided mesh. The second capillary structure 15 is disposed in the heat absorption section 16. The channels 151 transversely and longitudinally intersect each other. The second capillary structure 15 is disposed on one side of the second board body 12 in adjacency to the first capillary structure 13. The channels 151 transversely and longitudinally intersect each other so that the liquid working fluid 2 can go back to the heat absorption section 16 in a radial direction Y of the main body 1.

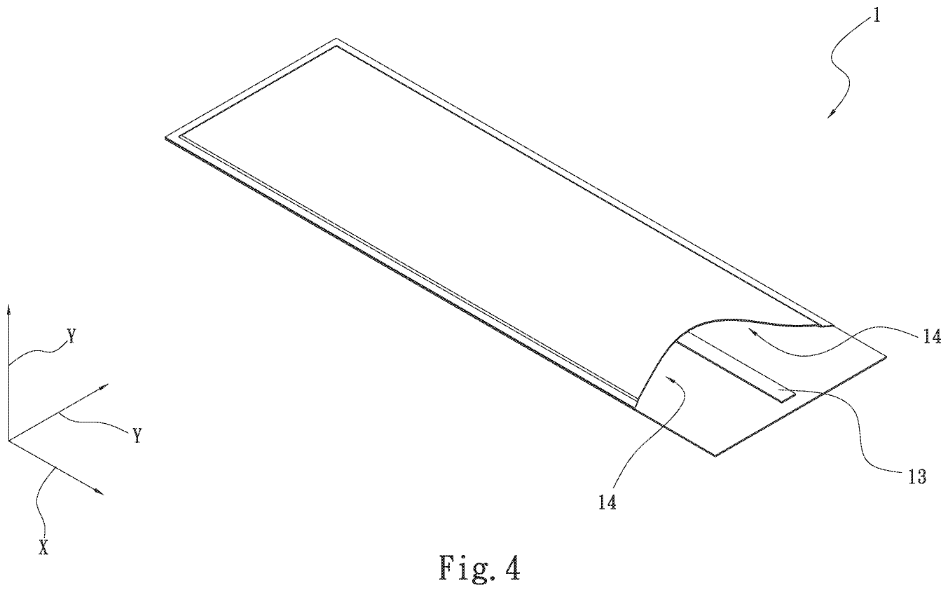

Please now refer to FIG. 4, which is a sectional assembled view of a third embodiment of the flat-plate heat pipe structure of the present invention. The third embodiment is partially identical to the first embodiment in structure and technical characteristic and thus will not be repeatedly described. The third embodiment is different from the first embodiment in that the first capillary structure 13 is disposed at the center of the main body 1 and extends in an axial direction X of the main body 1. The vapor passage 14 is disposed on two sides of the first capillary structure 13.

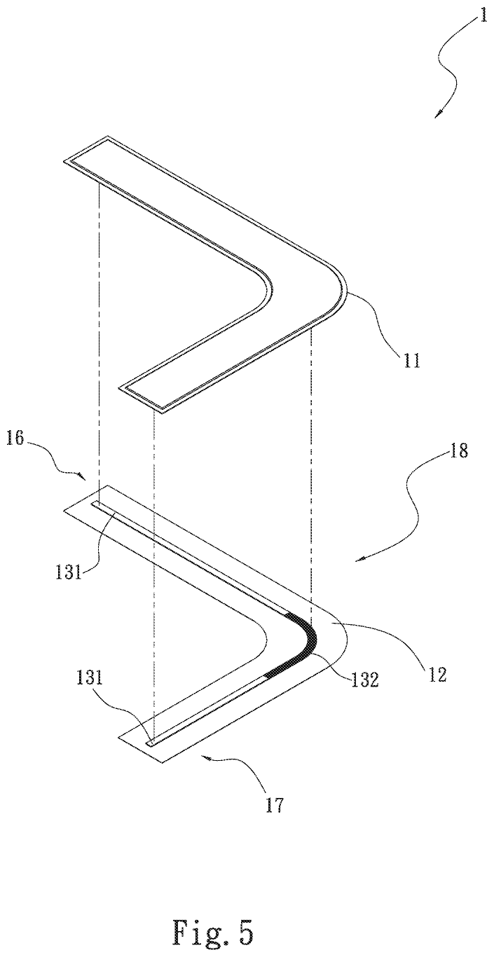

Please now refer to FIG. 5, which is a sectional assembled view of a fourth embodiment of the flat-plate heat pipe structure of the present invention. The fourth embodiment is partially identical to the first embodiment in structure and technical characteristic and thus will not be repeatedly described. The fourth embodiment is different from the first embodiment in that the first capillary structure 13 is a complex capillary structure. The main body 1 has a turning section 18. The heat absorption section 16 and the heat dissipation section 17 are connected with the turning section 18. The first capillary structure 13 disposed in the heat absorption section 16 and the heat dissipation section 17 is mainly a sintered powder body 131, while the first capillary structure 13 disposed in the turning section is a mesh body 132. In manufacturing, the first and second board bodies 11, 12 and the first capillary structure 13 of the main body 1 are laminated and assembled and then the open side of the main body 1 is sealed. Accordingly, the first and second board bodies 11, 12 can be first made with a bent form and then the first capillary structure 13 is disposed on either of the first and second board bodies 11, 12. Therefore, the problem of the conventional heat pipe that the heat pipe is bent after formed so that the capillary structure in the heat pipe will be damaged is solved.

The present invention has been described with the above embodiments thereof and it is understood that many changes and modifications in the above embodiments can be carried out without departing from the scope and the spirit of the invention that is intended to be limited only by the appended claims.

What is claimed is:

1. A thin flat-plate heat pipe structure comprising a main body, the main body having a first board body, a second board body, a pair of first capillary structures, a second capillary structure and a working fluid, the first and second board bodies being overlapped and mated with each other, the pair of first capillary structures and the second capillary structure being disposed between the first and second board bodies, the first capillary structure and the first and second board bodies together defining at least one vapor passage, and the vapor passage of the main body having a heat absorption section and a heat dissipation section; and
wherein the pair of first capillary structures are disposed at two lateral sides of the vapor passage abutting sidewalls of the main body and extend in an axial direction of the vapor passage, and the vapor passage is formed between the pair of the first capillary structures, the second capillary structure being disposed in the heat absorption section and between the pair of first capillary structures.

2. A thin flat-plate heat pipe structure comprising:
a main body having a first board body, a second board body, a pair of first capillary structures and a working fluid, the first and second board bodies being overlapped and mated with each other, a heat absorption section and a heat dissipation section defined between the first board body and the second board body at two end of the main body, the pair of first capillary structures being disposed at two lateral sides abutting two sidewalls of the main body and extend from the heat absorption section to the heat dissipation section;
a central vapor passage defined between the pair of first capillary structures and extend in an axial direction of the main body;
a second capillary structure transversely and longitudinally intersecting each other to cover with the heat absorption section and adjoined the pair of first capillary structure;
wherein the liquid working fluid go back from the heat dissipation section to the heat absorption section in the axial direction of the main body through the pair of the first capillary structure, and in a radial direction of the main body through the second capillary structure.

3. The thin flat-plate heat pipe structure as claimed in claim 2, wherein the first capillary structure is selected from a group consisting of mesh body, fiber body, linear braided body and sintered powder body.

4. The thin flat-plate heat pipe structure as claimed in claim 2, wherein the second capillary structure being multiple channels or braided mesh.

5. The thin flat-plate heat pipe structure as claimed in claim 2, wherein a thickness defined by the first and second board bodies ranges from 0.01 mm to 0.15 mm.
